(19) United States
(12) Patent Application Publication
(10) Pub. No.: US 2012/0153418 A1
(43) Pub. Date: Jun. 21, 2012

(54) SOLID-STATE IMAGING DEVICE AND MANUFACTURING METHOD THEREOF

(76) Inventor: Kazuhiko NAKADATE, Yokohama-shi (JP)

(21) Appl. No.: 13/234,229

(22) Filed: Sep. 16, 2011

(30) Foreign Application Priority Data
Dec. 15, 2010 (JP) 2010-279391

(51) Int. Cl. H01L 31/0232; H01L 31/18

(52) U.S. Cl. 257/432; 438/73; 257/E31.127; 257/E31.11

(57) ABSTRACT

According to one embodiment, a solid-state imaging device includes photodiodes provided in a substrate, and includes semiconductor regions of a first conductivity type, respectively, and an element isolation region provided in the substrate, includes a semiconductor region of a second conductivity type, and configured to electrically isolate the photodiodes from each other. The element isolation region is tilted in a direction of the center of an image area in which the photodiodes are arrayed.

### CROSS-REFERENCE TO RELATED APPLICATIONS

This application is based upon and claims the benefit of priority from prior Japanese Patent Application No. 2010-279391, filed Dec. 15, 2010, the entire contents of which are incorporated herein by reference.

### FIELD

Embodiments described herein relate generally to a solid-state imaging device and a manufacturing method thereof.

### BACKGROUND

A solid-state imaging device is used for a variety of purposes such as a digital still camera, a video camera, or a monitoring camera. A CCD image sensor or a CMOS image sensor is widely used as this solid-state imaging device.

The solid-state imaging device includes photodiodes which convert an optical signal into an electrical signal, and electrically read out an image projected onto its image area. A backside illumination solid-state imaging device has been developed as well. This solid-state imaging device has a structure in which photodiodes are provided on the backside (light-receiving surface side) of a semiconductor substrate, and an interconnection layer used to input/output an electrical signal to/from the outside is provided on the surface of the semiconductor substrate, which is opposite to the light-receiving surface of the semiconductor substrate. With this development, pixel miniaturization has further progressed.

Each photodiode has a depth nearly equal to the film thickness of the semiconductor substrate. Therefore, light impinges on the photodiode at a given angle with respect to a direction perpendicular to the light-receiving surface on the periphery of the image area, thus lowering the light incident efficiency. Furthermore, as microfabrication of photodiodes makes further advances, the light incident efficiency further degrades. This lowers the light reception sensitivity of the solid-state imaging device.

### BRIEF DESCRIPTION OF THE DRAWINGS

FIG. 1 is a plan view showing the configuration of a solid-state imaging device according to the first embodiment;

FIG. 2 is a sectional view of the solid-state imaging device taken along line A-A′ in FIG. 1;

FIG. 3 is a view for explaining an example of the arrangement of color filters of the solid-state imaging device;

FIG. 4 is a schematic view for explaining scaling of an image area of the solid-state imaging device;

FIG. 5 is a plan view showing the configuration of an element isolation region of the solid-state imaging device;

FIG. 6 is a plan view showing the manufacturing process of the solid-state imaging device;

FIG. 7 is a sectional view showing the manufacturing process of the solid-state imaging device;

FIG. 8 is a sectional view showing the manufacturing process of the solid-state imaging device;

FIG. 9 is a sectional view showing the manufacturing process of the solid-state imaging device;

FIG. 10 is a sectional view showing the manufacturing process of the solid-state imaging device;

FIG. 11 is a sectional view showing the manufacturing process of the solid-state imaging device;

FIG. 12 is a sectional view showing the manufacturing process of the solid-state imaging device;

FIG. 13 is a sectional view showing the manufacturing process of the solid-state imaging device;

FIG. 14 is a sectional view showing the configuration of a solid-state imaging device according to the second embodiment;

FIG. 15 is a schematic view showing an image area of a solid-state imaging device according to the third embodiment; and

FIG. 16 is a sectional view showing the configuration of pixels arranged at the central portion of the solid-state imaging device.

### DETAILED DESCRIPTION

In general, according to one embodiment, there is provided a solid-state imaging device comprising:

photodiodes provided in a substrate, and comprising semiconductor regions of a first conductivity type, respectively; and

an element isolation region provided in the substrate, comprising a semiconductor region of a second conductivity type, and configured to electrically isolate the photodiodes from each other,

wherein the element isolation region is tilted in a direction of the center of an image area in which the photodiodes are arrayed.

The embodiments will be described hereinafter with reference to the accompanying drawings. In the description which follows, the same or functionally equivalent elements are denoted by the same reference numerals, to thereby simplify the description.

### First Embodiment

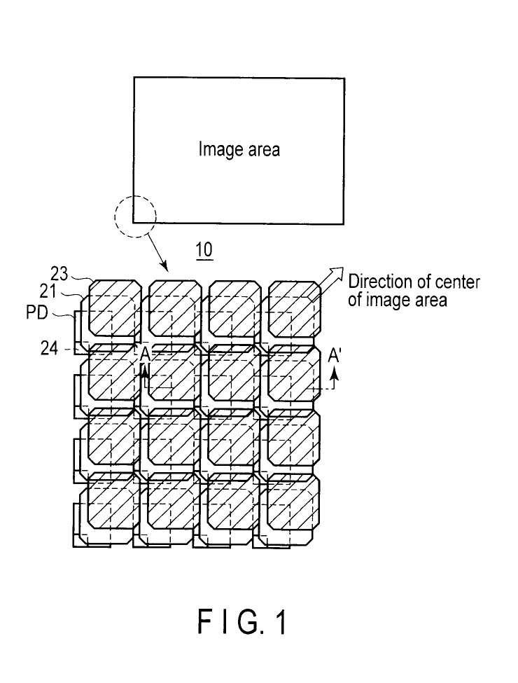

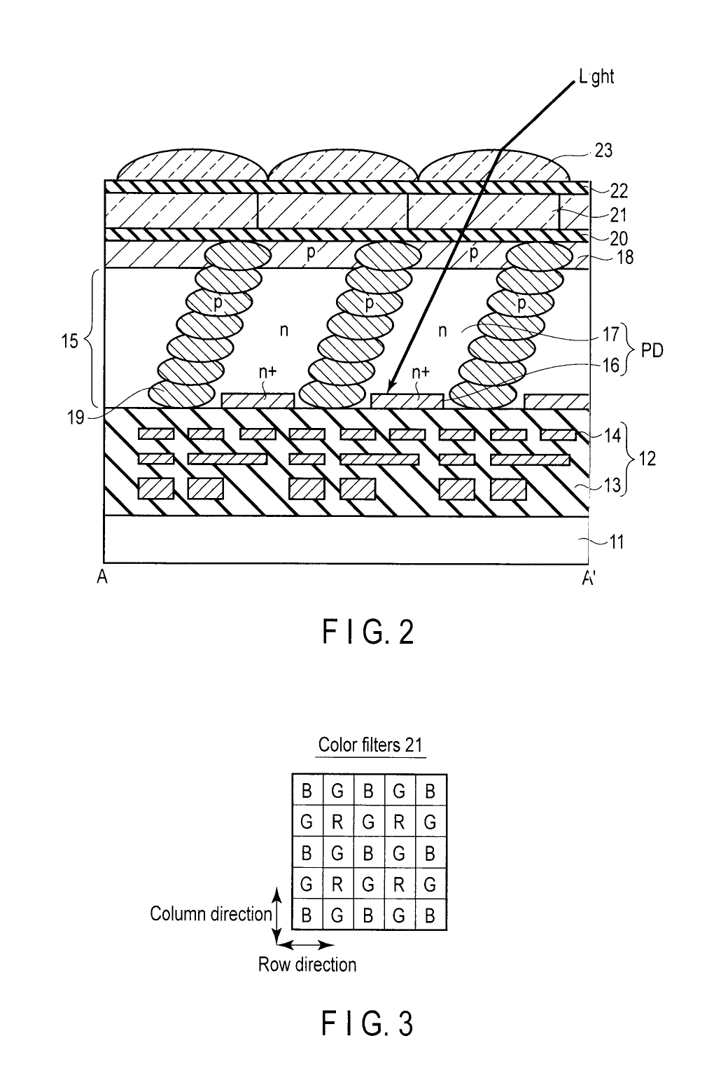

FIG. 1 is a plan view showing the configuration of a solid-state imaging device 10 according to the first embodiment. FIG. 2 is a sectional view of the solid-state imaging device 10 taken along line A-A′ in FIG. 1.

A support substrate 11 is provided to increase the strength and rigidity of the entire solid-state imaging device 10, and is made of, for example, silicon (Si). A multilayer interconnection layer 12 to serve as an interconnection structure is provided on the support substrate 11. The multilayer interconnection layer 12 includes an interlayer dielectric layer 13 made of, for example, silicon oxide, and a multilayer metal interconnection 14 provided in the interlayer dielectric layer 13. The multilayer interconnection layer 12 is provided with transfer gates 24 used to read out the charges of corresponding photodiodes.

An n-type semiconductor substrate 15 made of, for example, silicon (Si) is provided on the multilayer interconnection layer 12. The semiconductor substrate 15 may use an n-type epitaxial layer made of silicon (Si) or an n-type well formed in a substrate. A front side of the semiconductor substrate 15 corresponds to a surface in contact with the multilayer interconnection layer 12, and a backside of the semiconductor substrate 15 corresponds to a surface provided on the color filter. The backside of the semiconductor substrate 15 serves as a light-receiving surface.

A plurality of photodiodes PD are provided in the semiconductor substrate 15 in a matrix. The photodiodes PD are electrically isolated by a grid-shaped (meshed) element isolation region 19. The element isolation region 19 comprises a p-type semiconductor region formed by doping a p-type impurity such as boron (B) into the semiconductor substrate 15. More detailed configuration of the element isolation region 19 will be described later.

An example in which one pixel includes one photodiode PD will be given herein. Each photodiode PD includes a charge storage region 17 and n⁺-type semiconductor region 16. The charge storage region 17 comprises an n-type semiconductor region and functions as a light-receiving portion which photoelectrically converts incident light. The n⁺-type semiconductor region 16 has a function of collecting charges stored in the charge storage region 17. The n⁺-type semiconductor region 16 is provided in the lower portion of the photodiode PD, and is formed by doping a high-concentration n-type impurity such as phosphorus (P) into the semiconductor substrate 15. The photodiodes PD have a nearly square planar shape.

A p-type semiconductor layer 18 is provided on the photodiodes PD. The p-type semiconductor layer 18 functions as an element isolation region which electrically isolates the photodiodes PD, like the element isolation region 19.

A planarizing film 20 made of, for example, silicon oxide is provided on the p-type semiconductor layer 18. A color filter 21 is provided on the planarizing film 20 for each pixel. The color filters 21 include red filters R which mainly transmit light in the red wavelength range, green filters G which mainly transmit light in the green wavelength range, and blue filters B which mainly transmit light in the blue wavelength range. FIG. 3 is a view for explaining an example of the arrangement of color filters 21. Note that. FIG. 3 illustrates color filters equal in number to 5×5 pixels. In this embodiment, the color filters 21 are arranged using, for example, the Bayer arrangement. Adjacent color filters R, G, and B are arranged so as to obtain different color signals in the row and column directions, as shown in FIG. 3.

A protective film 22 made of, for example, silicon oxide is provided on the color filters 21. Microlenses (condenser lenses) 23 equal in number to the pixels are provided on the protective film 22.

With such a configuration, the solid-state imaging device 10 according to this embodiment can receive and detect incident light by guiding the incident light from the upper position in FIG. 2 and photoelectrically converting the incident light using the charge storage regions 17 of the photodiodes PD. The solid-state imaging device 10 receives light from the upper position on the side (backside) opposite to the side (front side) of the multilayer interconnection layer 12 present in the lower portion when viewed from the semiconductor substrate 15 including the photodiodes PD formed in it. Hence, the solid-state imaging device 10 has the so-called backside illumination structure.

In general, light guided from a camera lens to the photodiodes PD has an angle of incidence which varies between the center and periphery of the image area. Hence, the microlenses 23 and color filters 21 are shifted (so-called scaling) more in the direction of the center of the image area from positions of the photodiodes PD toward the periphery of the image area, thereby effectively guiding light even in the peripheral portion of the image area.

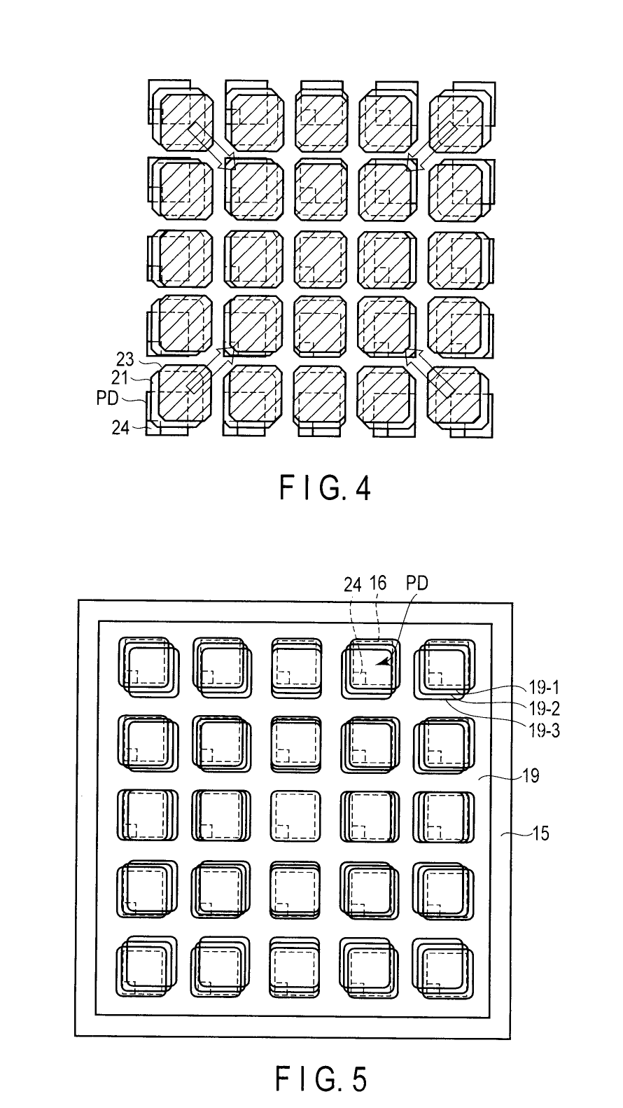

FIG. 4 is a schematic view for explaining scaling of the image area. Note that for the sake of simplicity, FIG. 4 illustrates scaling when the image area comprises 5×5 pixels. As can be seen from FIG. 4, the microlenses 23 and color filters 21 are shifted (so-called scaling) more in the direction of the center of the image area from the centers of the photodiodes PD (more specifically, the n⁺-type semiconductor regions 16) toward the periphery of the image area. Also, the transfer gate 24 and interconnection layer included in each pixel are arranged below the n⁺-type semiconductor regions 16 of the photodiodes PD in accordance with the scaling.

Note that as can be seen from FIG. 2, the element isolation region 19 which isolates the photodiodes PD is tilted more in the direction of the image area toward the periphery of the image area. In other words, the element isolation region 19 is configured to have a tilt in the direction of the center of the image area, which increases in a direction away from the center of the image area. To implement the element isolation region 19 with such a structure, the element isolation region 19 is formed by obliquely stacking a plurality of p-type diffusion layers so that they are shifted more in the direction of the center of the image area toward the top.

FIG. 5 is a plan view showing the configuration of the element isolation region 19. Squares indicated by solid lines in FIG. 5 show the boundaries between the photodiodes PD and the p-type diffusion layers which form the element isolation region 19. Also, for the sake of simplicity, FIG. 5 shows only three p-type diffusion layers 19-1 to 19-3 as the p-type diffusion layers which form the element isolation region 19. Upon forming the element isolation region 19, as shown in FIG. 5, the photodiodes PD isolated by the element isolation region 19 are tilted more in the direction of the center of the image area toward the periphery of the image area. This makes it possible to effectively guide light onto the photodiodes PD even on the peripheral portion of the image area, thus improving the light reception sensitivity.

### (Manufacturing Method)

A manufacturing method of a solid-state imaging device 10 will be described next with reference to the accompanying drawings.

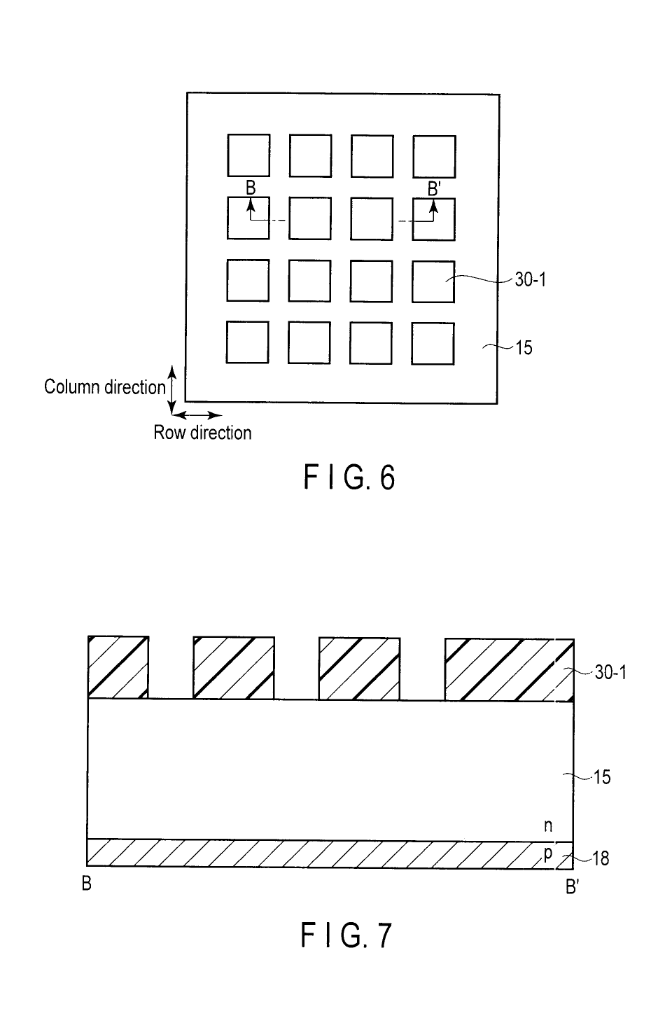

FIG. 6 is a plan view showing the manufacturing process of the solid-state imaging device 10, and FIG. 7 is a sectional view taken along line B-3′ in FIG. 6. Note that the plan view shown in FIG. 6 corresponds to the same portion of the image area as the plan view shown in FIG. 1.

First, an n-type semiconductor substrate 15 including a p-type semiconductor layer 18 formed on its backside is prepared. Referring to FIG. 7, the front side of the semiconductor substrate 15 faces up. Next, a resist pattern comprising a plurality of resist layers 30-1 is formed on the semiconductor substrate 15 by the first lithography process. The resist Pattern comprises resist layers 30-1 arranged with predetermined spacings between them in the row and column directions. Each resist layer 30-1 has the same square shape as the planar shape of each photodiode PD. Also, a region exposed by the resist pattern has the same grid shape as the planar shape of an element isolation region 19.

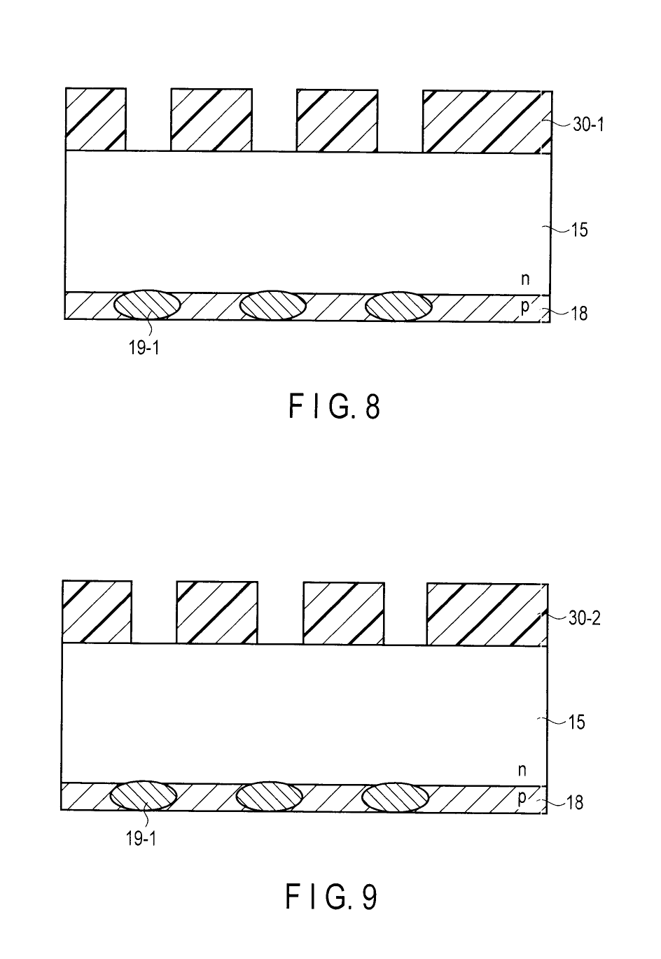

A p-type impurity is ion-implanted into the semiconductor substrate 15 using resist layers 30-1 as a mask by the first ion implantation process, as shown in FIG. 8. At this time, by setting a relatively high ion implantation acceleration energy, the impurity ions reach the p-type semiconductor layer 18 to form a p-type diffusion layer 19-1 in a lower portion of the semiconductor substrate 15. Thus, p-type semiconductor region 19-1 is formed in the lower portion of the semiconductor substrate 15 in a grid pattern. After that, resist layers 30-1 are removed.

A resist pattern comprising a plurality of resist layers 30-2 is formed on the semiconductor substrate 15 by the second lithography process, as shown in FIG. 9. The resist layers 30-2 are shifted more in the direction of the center of the image area from the centers of resist layers 30-1 toward the periphery of the image area. Each resist layer 30-2 has the same planar shape as that of each resist layer 30-1.

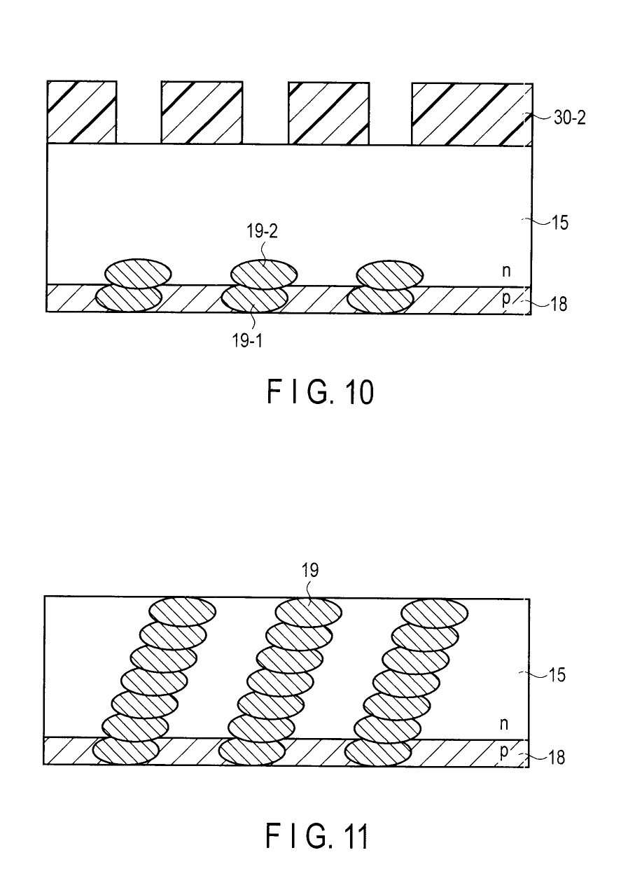

A p-type impurity is ion-implanted into the semiconductor substrate 15 using resist layers 30-2 as a mask by the second ion implantation process, as shown in FIG. 10. At this time, by setting an ion implantation acceleration energy lower than that in the first ion implantation process, a p-type semiconductor region 19-2 is formed on p-type semiconductor region 19-1 so as to bring them into contact with each other. Thus, p-type semiconductor region 19-2 is formed in the semiconductor substrate 15 in a grid pattern to be shifted more in the direction of the center of the image area from p-type semiconductor region 19-1 toward the periphery of the image area. After that, resist layers 30-2 are removed.

A lithography process and an ion implantation process are similarly repeated a plurality of times while changing the ion acceleration energy (changing the ion implantation depth). Thus, an element isolation region 19 is formed in the semiconductor substrate 15 to reach the front side of the semiconductor substrate 15, as shown in FIG. 11.

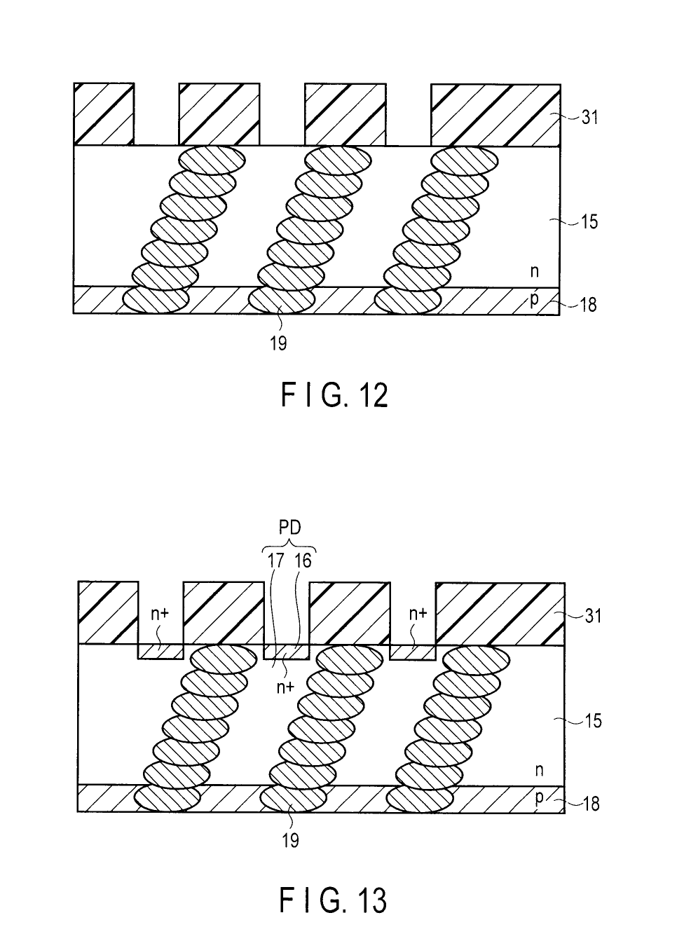

A resist layer 31 which exposes regions where photodiodes PD are to be formed is formed on toe semiconductor substrate 15 by a lithography process, as shown in FIG. 12. An n-type impurity is ion-implanted into the semiconductor substrate 15 using the resist layer 31 as a mask by an ion implantation process, as shown in FIG. 13. Thus, n⁺-type semiconductor regions 16 which form photodiodes PD are formed in regions of the semiconductor substrate 15 on the front side. In this manner, a plurality of photodiodes PD which are electrically isolated by the element isolation region 19 and have a nearly square planar shape are formed in the semiconductor substrate 15.

Lastly, a solid-state imaging device 10 shown in FIG. 2 is formed by a general manufacturing method using the semiconductor substrate 15 including the photodiodes PD and element isolation region 19 formed in it.

### (Effect)

As has been described in detail above, in the first embodiment, the backside illumination solid-state imaging device 10 includes, in the semiconductor substrate 15, the photodiodes PD and the grid-shaped element isolation region 19 which electrically isolates the photodiodes PD. The element isolation region 19 comprises a p-type semiconductor region formed by doping a p-type impurity into the semiconductor substrate 15. The element isolation region 19 is tilted (scaled) more in the direction of the center of the image area toward the periphery of the image area.

Hence, according to the first embodiment, the photodiodes PD are formed to be tilted more in the direction of the center of the image area toward the periphery of the image area. This makes it possible to improve the light incident efficiency and the Light reception sensitivity on the peripheral portion of the image area. This, in turn, makes it possible to attain a solid-state imaging device 10 capable of obtaining good image quality over the entire image area.

Similarly, the color filters 21 and microlenses 23 are scaled as well. This makes it possible to effectively guide light onto the photodiodes PD.

Note that the element isolation region 19 comprising a p-type semiconductor region need not always be formed up to the front side of the semiconductor substrate 15. For example, an element isolation insulating layer is formed in a region of the semiconductor substrate 15 on the front side, and covered with a p-type semiconductor region. The element isolation region comprising the p-type semiconductor region may then be formed to extend from the p-type semiconductor region to the backside of the semiconductor substrate 15. That is, according to this modification, the element isolation region 19 according to this embodiment comprises an element isolation insulating layer and p-type semiconductor region.

Also, the color filters 21 and microlenses 23 may be scaled, as shown in this embodiment, but the present embodiment is not limited to this. The color filters 21 and microlenses 23 may be arranged to have centers which nearly coincide with those of the light-receiving surfaces of the photodiodes PD.

### Second Embodiment

In the second embodiment, a plurality of photodiodes comprising n-type semiconductor regions are formed in a p-type semiconductor substrate such that they are tilted more in the direction of the center of the image area toward the periphery of the image area.

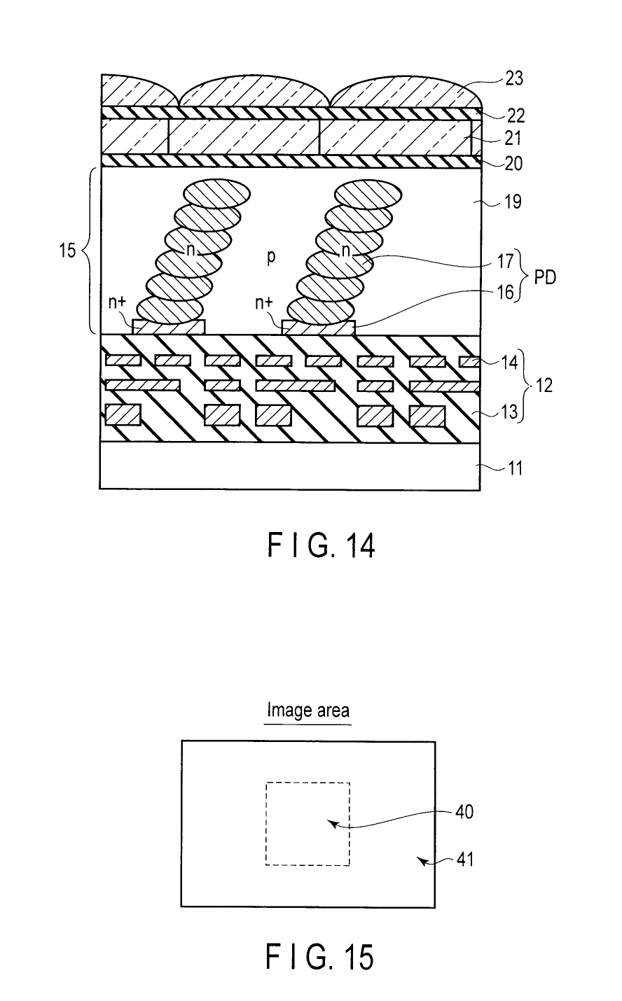

FIG. 14 is a sectional view showing the configuration of a solid-state imaging device 10 according to the second embodiment. A p-type semiconductor substrate 15 made of, for example, silicon (Si) is provided on a multilayer interconnection layer 12. The p-type semiconductor substrate 15 may use a p-type epitaxial layer made of silicon (Si) or a p-type well formed in a substrate.

A plurality of photodiodes PD are provided in the semiconductor substrate 15 in a matrix. Each photodiode PD includes a charge storage region 17 and n⁺-type semiconductor region 16. The charge storage region 17 comprises an n-type semiconductor region and functions as a light-receiving portion which photoelectrically converts incident light. The photodiodes PD have a nearly square planar shape.

The photodiodes PD are tilted more in the direction of the center of the image area toward the periphery of the image area. To implement the photodiodes PD with such a structure, the charge storage regions 17 are formed by obliquely stacking a plurality of n-type diffusion layers so that they are shifted more in the direction of the center of the image area toward the top. The charge storage regions 17 of the photodiodes PD can be formed by repeating a lithography process and an ion implantation process by a plurality of times while changing the acceleration energy (changing the ion implantation depth) of n-type impurity ions.

A region other than the photodiodes PD in the semiconductor substrate 15 serves as an element isolation region 19 comprising a p-type semiconductor region. Also, by setting the upper surfaces of the photodiodes PD at a level lower than that of the upper surface of the element isolation region 19, the upper portions of the photodiodes PD can electrically be isolated by the p-type semiconductor region.

As has been described in detail above, according to the second embodiment, the photodiodes PD are formed to be tilted more in the direction of the center of the image area toward the periphery of the image area. This makes it possible to improve the light incident efficiency and the light reception sensitivity on the peripheral portion of the image area. This, in turn, makes it possible to attain a solid-state imaging device 10 capable of obtaining good image quality over the entire image area.

### Third Embodiment

In the third embodiment, the image area is divided into a central portion including its center, and a peripheral portion which surrounds this central portion, and an element isolation region is titled only on the peripheral portion.

FIG. 15 is a schematic view showing an image area according to the third embodiment. The image area is divided into a central portion 40 including its center, and a peripheral portion 41 which surrounds the central portion 40. In pixels arranged on the peripheral portion 41, an element isolation region 19 is tilted (scaled) more in the direction of the center of the image area toward the periphery of the image area, in the same way as in FIG. 2 of the first embodiment. Thus, in the peripheral portion 41, photodiodes PD are formed to be tilted more in the direction of the center of the image area toward the periphery of the image area.

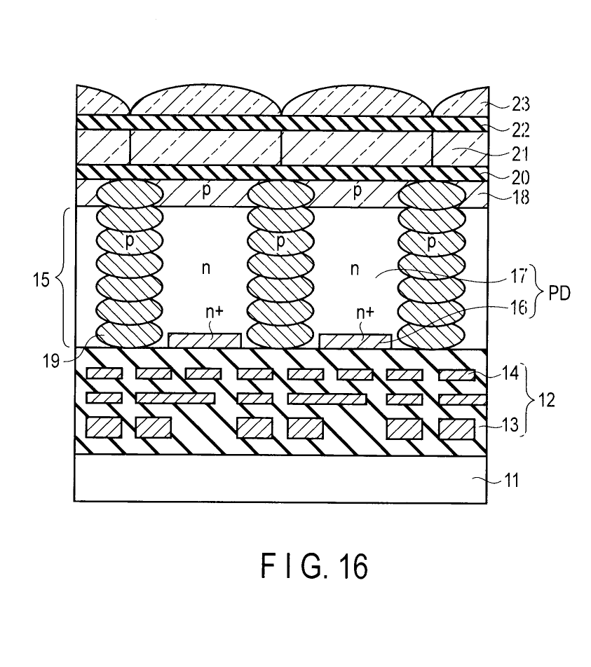

On the other hand, in pixels arranged at the central portion 40, light strikes the light-receiving surfaces of photodiodes PD at an angle of incidence close to 90° with respect to the light-receiving surface. Hence, in this embodiment, the element isolation region 19 and photodiodes PD are not scaled in the pixels arranged at the central portion 40. FIG. 16 is a sectional view showing the configuration of pixels arranged at the central portion 40.

The element isolation region 19 which electrically isolates the photodiodes PD is formed in a grid pattern to extend in a direction perpendicular to the light-receiving surface. Therefore, the photodiodes PD are also formed to extend in a direction perpendicular to the light-receiving surfaces of the photodiodes PD. The photodiodes PD have a nearly square planar shape. Color filters 21 and microlenses 23 arranged above the photodiodes PD are not scaled, either.

As has been described in detail above, according to the third embodiment, it is possible to improve the light incident efficiency and the light reception sensitivity on the peripheral portion 41 of the image area while ensuring a given light reception sensitivity at the central portion 40 of the image area. This, in turn, makes it possible to attain a solid-state imaging device 10 capable of obtaining good image quality over the entire image area.

Note that the element isolation region 19 and photodiodes PD on the peripheral portion 41 are not limited to the configuration according to the first embodiment, and may be tilted in the direction of the center of the image area at the same angle. It is also possible to apply the second embodiment to the third embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A solid-state imaging device comprising:
photodiodes provided in a substrate, and comprising semiconductor regions of a first conductivity type, respectively; and
an element isolation region provided in the substrate, comprising a semiconductor region of a second conductivity type, and configured to electrically isolate the photodiodes from each other,
wherein the element isolation region is tilted in a direction of the center of an image area in which the photodiodes are arrayed.

2. The device of claim 1, wherein a tilt of the element isolation region becomes greater as the element isolation region is away from the center of the image area.

3. The device of claim 1, wherein the element isolation region is tilted at the same angle.

4. The device of claim 1, wherein a planar shape of the element isolation region is a grid shape.

5. The device of claim 1, wherein
the image area is divided into a central portion and a peripheral portion,
the element isolation region of the central portion extends in a direction perpendicular to a light-receiving surface of the substrate, and
the element isolation region of the peripheral portion is tilted in the direction of the center of the image area.

6. The device of claim 1, wherein the device comprises a backside illumination type.

7. The device of claim 6, further comprising:
color filters provided on a light-receiving surface of the substrate;
condenser lenses provided on the color filters, respectively; and
an interconnection layer provided on a surface of the substrate, which is opposite to a light-receiving surface of the substrate.

8. The device of claim 1, further comprising a semiconductor layer provided on a light-receiving surface of the substrate, configured to electrically isolate the photodiodes from each other, and having a second conductivity type.

9. The device of claim 1, further comprising
condenser lenses provided on a light-receiving surface of the substrate in correspondence with the photodiodes,
wherein the condenser lenses are shifted in the direction of the center of the image area from positions of the photodiodes.

10. The device of claim 1, wherein
the first conductivity type is n type, and
the second conductivity type is p type.

11. A manufacturing method of a solid-state imaging device including an image area in which photodiodes are arrayed, the method comprising:
preparing a semiconductor substrate of a first conductivity type; and
forming an element isolation region in the semiconductor substrate region, the element isolation region electrically isolating the photodiodes from each other and being tilted in a direction of the center of the image area,
wherein the forming the element isolation region includes repeating forming a resist layer on the semiconductor substrate, and doping an impurity of a second conductivity type into the semiconductor substrate using the resist layer as a mask, and
the resist layer is formed to be shifted in the direction of the center of the image area every time the number of times of the repeating increases.

12. The method of claim 11, wherein a tilt of the element isolation region becomes greater as the element isolation region is away from the center of the image area.

13. The method of claim 11, wherein a planar shape of the element isolation region is a grid shape.

14. The method of claim 11, wherein the impurity is doped from a surface of the semiconductor substrate, which is opposite to a light-receiving surface of the semiconductor substrate.

15. The method of claim 11, wherein an impurity acceleration energy decreases every time the number of times of the repeating increases.

16. The method of claim 11, wherein
the first conductivity type is n type, and
the second conductivity type is p type.
